(19) United States
(12) Patent Application Publication
(10) Pub. No.: US 2012/0097222 A1
(43) Pub. Date: Apr. 26, 2012

(54) TRANSPARENT CONDUCTING OXIDE FILMS WITH IMPROVED PROPERTIES

(75) Inventors: TIMOTHY A. GESSERT, Golden, CO (US); Xiaonan Li, Evergreen, CO (US); Teresa Barnes, Golden, CO (US); Carrie L. Wyse, Longmont, CO (US)

(73) Assignee: ALLIANCE FOR SUSTAINABLE ENERGY, LLC, Golden, CO (US)

(21) Appl. No.: 13/282,280

(22) Filed: Oct. 26, 2011

Related U.S. Application Data
(60) Provisional application No. 61/383,974, filed on Oct. 26, 2010.

(51) Int. Cl. H01L 31/0224; H01B 1/00; C23C 16/40; B32B 17/06; B05D 5/12; B05D 5/00

(52) U.S. Cl. 136/252; 427/126.3; 427/126.2; 428/426; 252/520.1

(57) ABSTRACT

A method of producing thin-film transparent conducting oxide (TCO) materials and devices that incorporate the transparent conducting oxide materials are disclosed. The method described is for coating glass, polymers, foils, or electronic devices with a TCO having improved characteristics.

### CROSS-REFERENCE TO RELATED APPLICATIONS

This application claims the benefit of U.S. Provisional Application No. 61/383,974, filed Oct. 26, 2010, which is incorporated herein by reference in its entirety.

### CONTRACTUAL ORIGIN

The United States Government has rights in this invention under Contract No. DE-AC36-08GO28308 between the United States Department of Energy and the Alliance for Sustainable Energy, LLC, the Manager and Operator of the National Renewable Energy Laboratory.

### BACKGROUND

The present disclosure generally relates to methods of producing thin-film transparent conducting oxide (TCO) materials and devices that incorporate the transparent conducting oxide materials. In particular, the present disclosure relates to a method of producing a transparent thin-film oxide material having high electron mobility and low resistivity, and devices such as photovoltaic cells that incorporate the transparent conducting oxide materials.

Transparent conducting oxide (TCO) coatings, such as thin-film tin oxide (SnO₂), are widely used in the manufacture of a variety of products including low-emissivity window glazings for construction glass and photovoltaic (PV) cells. SnO₂ is a particularly, attractive TCO coating due to several desirable material properties. SnO₂ TCO coatings do not contain any scarce materials such as indium, or any toxic materials such as cadmium. As a window glazing, SnO₂ is mechanically hard, chemically inert, functions as an excellent sodium diffusion barrier on soda-lime glass, and remains environmentally stable even in the presence of moisture. When incorporated into a PV cell, the resistivity of SnO₂ may be decreased to more useful levels through the incorporation of n-type dopants such as antimony, arsenic, chlorine, and fluorine to increase the carrier concentration. These doped SnO₂ coatings retain stable electrical and optical properties even under acidic or basic conditions and at the elevated temperatures used during the production of PV cells, which may be in excess of 650° C.

Doped SnO₂ coatings are typically used as a transparent electrode material for photovoltaic (PV) devices such as a-Si or CdTe thin-film solar panels, and the optical transparency of the doped SnO₂ coating is a particularly important material property governing a cell's efficiency at converting solar energy into electrical current. Typically, the electron mobility of a conventional commercial-grade SnO₂ is low relative to other TCO materials such as In-based coatings, Cd-based coatings, or research-grade SnO₂, which is manufactured using a different process than commercial-grade SnO₂. As a result, higher dopant levels are incorporated into the commercial-grade SnO₂ in order to reduce the resistivity of the commercial-grade SnO₂ to levels comparable to the other TCO coating materials. Unfortunately, the high carrier concentrations that result reduce the optical transparency of the doped commercial-grade SnO₂, due to impurity scattering effects, thereby reducing the efficiency of the PV cell. It has been estimated that this reduction in the optical transparency of commercial-grade SnO₂ transparent electrodes may potentially reduce the output of electrical current from a photovoltaic cell by as much as 10% compared to electrodes using research-grade SnO₂.

Although commercial-grade SnO₂ is an attractive material for the manufacture of PV cells, the efficiency of the resulting PV cells is ultimately limited by the relatively low electron mobility of the commercial-grade SnO₂ compared to other TCO materials. Further, although research-grade SnO₂ TCO coatings possess significantly higher electron mobilities, this material is currently produced only in small quantities due to the toxicity and environmental impact of the precursor materials used to form the SnO₂ coating using a chemical vapor deposition process.

The foregoing examples of the related art and limitations related therewith are intended to be illustrative and not exclusive. Other limitations of the related art will become apparent to those of skill in the art upon a reading of the specification and a study of the drawings.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 is a schematic diagram illustrating an exemplary method of producing a TCO coating on a substrate.

FIG. 2 is a schematic diagram of an exemplary photovoltaic that incorporates TCO coating produced using a method described herein.

Corresponding reference characters and labels indicate corresponding elements among the view of the drawings. The headings used in the figures should not be interpreted to limit the scope of the claims.

### DETAILED DESCRIPTION

One aspect of the present disclosure involves a method of producing a transparent conducting oxide coating on a substrate. The method involves heating a substrate in a processing chamber. The method further involves introducing a metal-containing precursor, oxygen or an oxygen containing precursor, and one or more dopant precursors that contain a high molecular weight halogen and a low molecular weight halogen into the processing chamber, forming a reactive mixture. Additionally, the method involves contacting the reactive mixture with the heated substrate to form a deposited layer comprising the transparent conducting oxide attached to the substrate, wherein the TCO has a Hall mobility ranging between about 20 cm²V⁻¹ s⁻¹ and about 200 cm²V⁻¹ s⁻¹ and a carrier concentration ranging between about 10¹⁷ cm⁻³ and about 10²² cm⁻³.

Another aspect of the present disclosure involves an apparatus comprising at least one transparent conducting oxide coating on a substrate produced using the methods discussed herein, wherein the apparatus is a photovoltaic cell, an electroluminescent display screen, or a low e-glass. A need exists for a method of producing a TCO coating material such a SnO₂ that possesses an electron mobility that is comparable to research-grade SnO₂ coatings and that also minimizes or otherwise reduces the drawbacks associated with existing research-grade production techniques such as the use of toxic precursor materials. The insights gained from this method may be further applied to the production of other TCO coating materials such as fluoride-doped cadmium oxide or zinc oxide. The TCO coating materials produced using such a method may be used to produce higher-efficiency photovoltaic cells resulting from the enhanced optical transparency of these coatings.

A method of producing a transparent conducting oxide (TCO) coating material is provided that overcomes limitations of previous production methods. For example, the method of producing a transparent conducting oxide (TCO) coating produces a coating with a relatively high electron mobility using a variety of precursor compounds, many of which may be utilized on a commercial scale. Thus, this method may be used to produce a TCO coating such as a fluorine-doped tin oxide on a commercial scale, which may be used in the large-scale production of highly efficient photovoltaic cells, among other uses.

It has been surprisingly discovered that the incorporation of high molecular weight (MW) halogen groups, such as bromine, into the precursor compounds used to produce a TCO coating produces a discernable difference in the crystal structure of the resulting coating compared to coatings produced in the absence of high molecular weight halogen groups. This difference in the structure of the TCO coating is associated with higher electron mobility relative to comparable TCO coatings produced using methods that do not incorporate high molecular weight halogen groups into the precursor compounds. As a result, the electron mobility of a TCO coating produced using this method may be specified to some degree by the proportion of high molecular weight halogen groups incorporated into the precursor compounds.

In addition, it has been surprisingly discovered that the incorporation of low MW halogen dopants, such as fluorine, into the TCO coating produced using this method enhances the electron mobility of the resulting doped TCO coating, contrary to the expected reduction in electron mobility predicted by impurity scattering mechanisms. Without being bound to any particular theory, the increase in mobility due to doping is thought to occur via a fluxing process in which the highly reactive high MW halon species improves both intragrain and intergrain quality of the TCO.

The TCO coatings produced using this method may include any TCO coating known in the art, in particular those coatings in which the inclusion of dopants is used to alter the inherent electrical properties of the undoped TCO material. Non-limiting examples of TCOs and other coating materials suitable for production using this method include tin oxide, zinc oxide, cadmium oxide, silicon oxide, indium-tin oxide, Pb—Zr—Ti oxide and other piezo-electric ceramics, carbon, silicon nitride, and super-conducting materials such as mercury-barium oxide, and mercury-barium-copper oxide. Any of these coating may be doped with one or more elements including, but not limited to, Group V and Group VII elements. In one possible example, the TCO material produced using the method is a fluorine-doped tin oxide (F:SnO₂) material.

The TCO coatings produced by this method have been observed to be polycrystalline in structure, and therefore the electron mobility and optical transparency of the TCO coatings produced using this method may be enhanced by the inclusion of dopants in sufficient amounts. In addition to altering the electrical properties of the films, the dopants may also affect the crystal structure, preferred orientation of the film, and its morphology. The changes in morphology include increased or decreased surface roughness, which would lead to increased or decreased optical haze in the film. The resulting doped TCO coatings produced using these methods may be used to produce high-efficiency electrical devices, such as photovoltaic cells.

Aspects of the method of producing a transparent TCO coating and exemplary electrical devices using the transparent TCO coating are described in detail below.

### I. Methods of Producing TCO Films

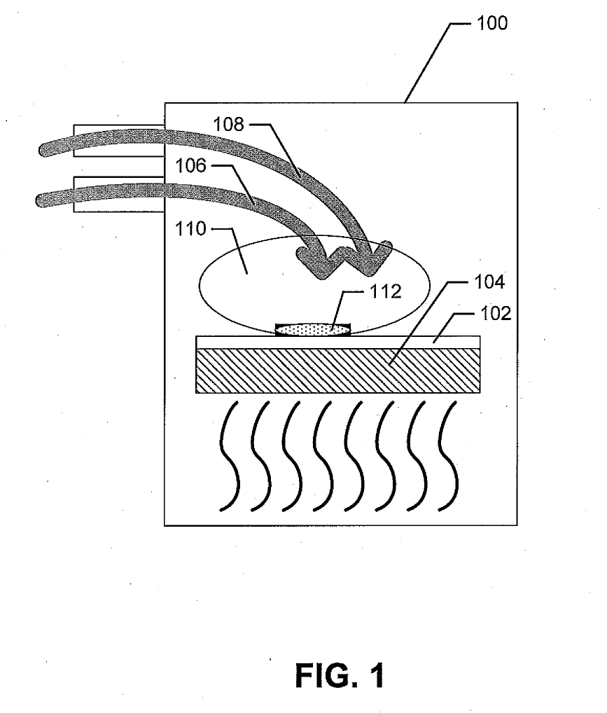

FIG. 1 is a schematic diagram illustrating the method of producing a TCO coating. This method of producing a transparent conducting oxide (TCO) coating 102 on a substrate 104 includes heating the substrate in a processing chamber 100, introducing a metal-containing precursor 108 and dopant precursors 108 that include a high molecular weight halogen group to form a reactive mixture 110. The TCO coating 102 may be formed as a deposited layer upon contact of the reactive mixture with the heated substrate, causing a reaction 112 which produces the TCO coating 102. The TCO coating 102 may be deposited in the form of a uniform film on the entire substrate, as shown in FIG. 1, in the form of a patterned film over exposed surfaces of the substrate, or in any other desired form.

The reaction of the precursor compounds may be activated in the processing chamber by any known method, including, but not limited to, thermal activation, plasma activation, pyrolysis, and any combination thereof. The TCO coating formed using this method has a Hall mobility ranging from about 20 cm²V⁻¹ s⁻¹ to about 200 cm²V⁻¹ s⁻¹ and a carrier concentration ranging from about 10¹⁷ cm⁻³ to about 10²² cm⁻³.

The method may make use of any known method of producing a TCO coating, including, but not limited to, chemical vapor deposition (CVD), spray pyrolysis, and sputtering. A CVD method may be used, which typically forms the TCO coating when the metal-containing precursor and the dopant precursor, or dissociated by-products of these precursors, react with one another upon contact with the heated substrate. As a result, either the metal-containing precursor or the dopant precursor may collectively contain all of the elements included in the TCO coating. For example, if a fluorine-doped tin oxide SnO₂ TCO coating is produced using a CVD method, the composition of the metal-containing precursor includes Sn, the composition of the dopant precursor includes fluorine (F) in addition to a high molecular weight halogen such as bromine (Br) or iodine (I), and one or both of the precursor compounds may include oxygen. Alternatively, if neither of the precursor compounds includes oxygen, an oxygen-containing precursor may be introduced into the processing chamber, along with the other precursor compositions.

Alternatively, the dopant precursor need not include the high molecular weight halogen group, and instead a separate dopant precursor and high molecular weight halogen precursor may be introduced into the processing chamber, along with the metal-containing precursor and a separate oxygen-containing precursor. By introducing the elements of the TCO coating as separate precursor compounds, the different TCO material properties resulting from variations in the relative proportions of each precursor may be varied independently. For example, the relative proportion of high MW halogen groups in the reactive mixture may govern the electron mobility, while the relative proportion of dopant in the reactive mixture may influence the optical transparency and/or carrier concentration of the TCO coating produced by the method.

Detailed descriptions of the processing chamber, the substrate, and the various precursor compounds are provided below.

a. Processing Chamber

The processing chamber may be any closed container capable of holding the substrate, supplying heat to the substrate and introducing the precursor compounds in a controlled proportion. The processing chamber may also be capable of providing a controlled pressure environment. If the method is carried out using chemical vapor deposition (CVD) techniques, any known CVD device may be used to produce the TCO coating on the substrate. Non-limiting examples of CVD devices suitable for carrying out the method include a low-pressure CVD chamber, an atmospheric-pressure CVD chamber, an ultra-high vacuum CVD chamber, and a plasma-assisted CVD chamber. If a plasma-assisted CVD chamber is selected, after introduction of the precursor compounds into the processing chamber, a plasma may be formed that includes species from the precursor compounds that may react to deposit the TCO layer on the substrate. If the method is carried out using spray pyrolysis techniques, the processing chamber may be a heated chamber in which the heated substrate is sprayed with liquid solutions that include the precursor compounds that may react and/or decompose to deposit the TCO layer on the substrate. Process options can also include reactive physical deposition processes including evaporation and sputtering, in which the reactive species include partial pressures of the dopant and high MW additions.

The reaction of the precursors may be initiated in the processing chamber by a variety of process conditions. The temperature in the processing chamber during TCO deposition may be selected to thermally activate one or more of the metal-containing precursors, the dopant precursor, the high molecular weight halogen precursor, and the oxygen precursor to deposit the metal oxide layer on the substrate surface. The temperature in the processing chamber may range between about 400° C. and about 700° C. In other aspects, the temperature in the processing chamber may range between about 400° C. and about 500° C., between about 450° C. and about 550° C., between about 500° C. and about 600° C., between about 550° C. and about 650° C., and between about 600° C. and about 700° C. The processing chamber may be configured to generate a plasma that includes one or more of the metal-containing precursor, the dopant precursor, the high molecular weight halogen precursor, and the oxygen precursor, which may be plasma activated to deposit the TCO layer on the substrate surface.

b. Substrate

The substrate may be selected from any material known to be suitable for TCO deposition, including, but not limited to, glass including soda-lime glass, silica, or various glass compositions such as borosilicate, alumniosilicate, or barium silicate. The glass substrate may be pre-coated with various coatings including cadmium sulfide (CdS), silica (SiOₓ) or other barrier coatings, undoped TCO coatings such as tin oxide (SnO₂), cadmium oxide (CdO), cadmium tin oxide (Cd₂SnO₄), zinc oxide (ZnO), and indium tin oxide (In₂O₃:Sn). The selection of substrate may be based any one of at least several factors, including, but not limited to, the material properties of the substrate at the temperatures at which the TCO coating is deposited, the reactivity of the substrate surface with the precursor compounds during deposition, and the intended use of the TCO coating. For example, if the TCO coating is to be used as a transparent electrode in a CdS/ClGS photovoltaic cell, the substrate may be the top CdS layer, or it may be a metal or polymer. As another example, if the TCO coating is to be used as a window glazing, the substrate may be soda-lime glass. As another example, if the TCO coatings to be used as a transparent electrode in a CdS/CdTe solar cell, the substrate may be soda lime glass, soda lime glass with a barrier coating, or a sodium-free (i.e. borosilicate) glass.

c. Metal-Containing Precursor

The metal-containing precursor may be selected from any known compound suitable for use in CVD, sputtering, or pyrolysis processes. In one aspect, the metal containing precursor includes any compound containing one or more metals to be included in the TCO coating. Non-limiting examples of metals suitable for inclusion in a TCO coating include tin (Sn), cadmium (Cd), zinc (Zn), indium (In), nickel (Ni), zirconium (Zr), vanadium (V), titanium (Ti), copper (Cu), and hafnium (Ha). The metal may be delivered using a liquid or vapor-phase organometallic precursor. Alternatively, the metal-containing precursor may comprise one or more metals covalently or ionically attached to one or more attached groups, including, but not limited to, alkanes, alkenes, alkynes, alcohols, halogens, ketones, aldehydes, carboxylic acids, ethers, esters, amines, amides, ketones, alehydes, oxygen, and perhalogenated alkyls. Non limiting examples of specific metal-containing precursor compounds include tetramethyltin (TMT), tin tetrachloride, dibutyl tin chloride, monobutyl tin chloride, tetraethyltin, monobutyltin oxide, dibutyltin oxide, mono/dibutyltin chlorides, dimethyltin dichloride, tin tetrafluoride, tin trichlorofluoride (SnCl₃F), SnCl₂F₂, SnIF₃, SnBrF₃, Sn(CF₃)₄, SnOF₂, SnO(CF₃)₂, SnOClF, SnOIF, SnOBrF, C₄H₁₀O₂Sn, C₈H₁₈OSn, C₄H₉SnCl₃ and the like. In an exemplary aspect, the metal-containing precursor is tetramethyltin.

The metal-containing precursor may be diluted in a carrier gas. Non-limiting examples of suitable carrier gases include inert gases such as N₂, He, and Ar, and gases with a combination of inert and reactive compounds such as air.

The amount or rate at which the metal-containing precursor is introduced into the processing chamber is dependent on one or more of at least several factors, including, but not limited to, the particular production method used such as CVD or surface pyrolysis, the process conditions such as chamber temperature and pressure, the desired composition of the TCO coating, and the presence and amount of other precursors. For example, if a fluorine doped tin oxide TCO coating is produced in a CVD chamber at a temperature of about 550° C. and pressure of about 40 Torr, using tetramethyl tin (TMT) as the metal-containing precursor, and oxygen supplied in the amount of about 45 mol %, the TMT may be supplied in the amount of about 0.5 mol % to about 0.6 mol %.

d. Dopant Precursor

The dopant precursor may be selected from any known compound containing one or more dopant elements that are suitable for use in CVD, sputtering, or pyrolysis processes. The one or more dopant elements may be elements known in the art to function effectively as a TCO dopant, including, but not limited to, one or more of the Group V or Group VII elements. Non-limiting examples of suitable dopant elements include nitrogen (N), phosphorus (P), arsenic (As), antimony (Sb), bismuth (Bi), polonium (Po), vanadium (V), niobium (Nb), tantalum (Ta), fluorine (F), chlorine (Cl), bromine (Br), iodine (I), and astatine (At). In an exemplary aspect, fluorine is selected as the dopant element.

The dopant precursor may comprise one or more dopant elements, either alone or in combination with other elements, including, but not limited to, carbon, oxygen, nitrogen, sulfur, boron and/or other halogens, among other elements. The dopant precursor may include one or more metal groups, including the metal to be incorporated into the TCO material to be produced using the method. Non-limiting examples of dopant precursors include carbon and fluorine containing compounds such as Halocarbons 116, 1216, 14, 218, 23, 32, 41, 4110, and/or C318, C₂BrF₃, CH₃F, CF₄, CF₂O, CHClF₂, C₂ClF₅, C₂ClF₃, CClF₃, CBr₂F₂, C₂Br₂F₄, CCl₂F₂, CHCl₂F, C₂Cl₂F₄, C₂H₃ClF₂, C₂H₄F₂, C₂H₂F₂, CH₂F₂, C₃F₆O, C₂F₆, C₃F₆, C₄F₈, C₄F₈O, C₅F₈, C₂H₅F, C₄F₁₀, C3F₈, C₂F₄, CCl₃F, C₂Cl₃F₃, CHF₃, C₂H₃F, and C₃F₇OCH₃, BF₃, HF, F₂O, SiF₄, SF₆, SF₄, S₂F₁₀, WF₆, AsF₅, PF₃, BrF₅, BrF₃, IF₅, ClF₃, NF₃, N₂F₄, ClF, BrF, ClF₂N, FCl₂N, XeF₂, GeF₄, ClF₃, F₂, a mixture of F₂ and O₂, a mixture of HF and O₂, F₃NO, FNO, COF₂, CF₃NO, CF₃OF, CF₃I, SClF₅, SO₂F₂, NCl₂F, NF₂Cl, ClFO₃ and the like. The dopant precursor may be provided as a single compound, or as a mixture of two or more dopant precursor compounds.

Additional non-limiting examples of dopant precursors include hydrofluorinated ethers (HFEs), having the structure as defined by Formula (I):

R₁—O—R₂ (I)

where R₁ and R₂ may be independently selected from C₁-C₄ alkyl groups which may have one or more hydrogens (—H) substituted with fluorines (—F). When either R₁ or R₂ is an unsubstituted alkyl group with no fluorine groups, then the other group R₁ or R₂ includes at least one fluorine group. Specific non-limiting examples of HFEs include C₄F₉OCH₃, C₄F₉OC₂H₅, CF₃OCH₃, CHF₂OCHF₂, CF₃CF₂OCH₃, CF₃OCHFCF₃, and CF₃COCBr₂H.

The amount or rate at which the dopant precursor is introduced into the processing chamber is dependent on one or more of at least several factors, including, but not limited to, the particular production method used such as CVD or surface pyrolysis, the process conditions such as chamber temperature and pressure, the desired composition of the TCO coating, the desired dopant concentration in the TCO material, and the presence and amount of other precursors. For example, if a fluorine-doped tin oxide TCO coating is produced using CBrF₃ as the dopant precursor in a CVD chamber at a temperature of about 550° C. and pressure of about 40 Torr, using tetramethyl tin (TMT) as the metal-containing precursor in the amount of about 0.5 mol % to about 0.6 mol %, and oxygen gas in the amount of about 45 mol %, the CBrF₃ may be supplied in an amount ranging from about 0.01 mol % to about 20 mol % depending on the desired dopant concentration and electron mobility of the resulting TCO coating.

e. High Molecular Weight Halogen Precursor

The inclusion of a high molecular weight halogen in the production of a TCO coating as described previously results in a TCO having enhanced electron mobility due to improved TCO material quality. Non-limiting examples of high-molecular weight halogens suitable for use in the method of producing enhanced electron mobility TCO coatings include iodine, bromine, and astatine. In an exemplary aspect of the method, the high molecular weight halogen included in the processing chamber is bromine.

The high molecular weight halogen may be provided as an attached group included within any of the precursor compounds discussed above, including, but not limited to, the metal-containing precursor, the dopant precursor, or the oxygen precursor. The high molecular weight halogen precursor may also be provided independently in the form of a high molecular weight halogen precursor compound. The high molecular weight halogen may be provided as one or more attached groups within the metal precursor compound, an attached group within the dopant precursor, an attached group within the oxygen, and a high molecular weight halogen precursor.

The high molecular weight halogen precursor includes any compound containing one or more of the high molecular weight halogen elements described above. Non-limiting examples of suitable high molecular weight halogen precursor compounds may be formed by substituting one or more of the high molecular weight halogens iodine, bromine, and astatine for any of the halogen groups included within one or more of the metal-containing precursor compounds and/or dopant precursor compounds described above.

In general, the high molecular weight halogen precursor may include one or more high molecular weight halogens, either alone or in combination with other elements, including, but not limited to, carbon, oxygen, nitrogen, sulfur, boron and/or other halogens, among other elements. The high molecular weight halogen precursor may include one or more metal groups, including the metal to be incorporated into the TCO material to be produced using the method. Specific non-limiting examples of suitable high molecular weight halogen precursor compounds include BrF₃C, IF₃C, HBr, HI, and HAs.

The amount or rate at which the high molecular weight halogen precursor is introduced into the processing chamber is dependent on one or more of at least several factors, including, but not limited to, the particular production method used such as CVD or surface pyrolysis, the process conditions such as chamber temperature and pressure, the desired composition of the TCO coating, and the presence and amount of other precursors. For example, if a fluorine-doped tin oxide TCO coating is produced using CBrF₃ as the dopant precursor that includes a high molecular weight halogen in a CVD chamber at a temperature of about 550° C. and pressure of about 40 Torr, using tetramethyl tin (TMT) as the metal-containing precursor in the amount of about 0.5 mol % to about 0.6 mol %, and oxygen gas in the amount of about 45 mol %, the CBrF₃ may be supplied in an amount ranging from about 0.01 mol % to about 20 mol % depending on the desired dopant concentration and electron mobility of the resulting TCO coating. The use of separate high and low molecular weight precursors enables variation in the ratio of high and low molecular weight halogen and the optimization of this ratio. It may be possible to identify a precursor combining high and low molecular weight halogens in an optimized ratio in a single molecule or it may be more beneficial to maintain separate high and low molecular weight halogen precursors in order to optimized the performance of the TCO coating. Separating the precursors also allows the independent optimization of the ratio of each halogen to metal precursor.

f. Oxygen Precursor

Because many of the TCO coating compositions produced by the method are oxides, oxygen may be an element supplied to the processing chamber, either individually or as part of the metal-containing precursor or the dopant precursor. The oxygen precursor may include any oxygen-containing compound suitable for the TCO deposition processes, such as CVD or surface pyrolysis. The oxygen precursor may be any one of the precursors described previously, so long as the previously-described precursor includes oxygen in its composition. In addition, the oxygen precursor may be an oxygen-containing compound supplied independently of the other precursor compounds. In some aspects, the oxygen precursor may function solely to furnish elemental oxygen to the deposition reactions at the surface of the substrate in the processing chamber, the oxygen precursor may be used to dilute other precursors, or the oxygen precursor may function as a carrier gas. Non-limiting examples of oxygen precursors include atomic oxygen (O), molecular oxygen (O₂), O₃, N₂O, NO, NO₂, OH, H₂O, H₂O₂, SO, SO₂, CO₂, C₃H₇OH, and C₂H₅OH.

The amount or rate at which the high molecular weight halogen precursor is introduced into the processing chamber is dependent on one or more of at least several factors, including, but not limited to, the particular production method used such as CVD or surface pyrolysis, the process conditions such as chamber temperature and pressure, the desired composition of the TCO coating, and the presence and amount of other precursors. For example, if a doped tin oxide TCO coating is produced using CBrF₃ as the dopant precursor in a CVD chamber at a temperature of about 550° C. and pressure of about 40 Torr, using tetramethyl tin (TMT) as the metal-containing precursor in the amount of about 0.5 mol % to about 0.6 mol %, oxygen gas may be supplied as the oxygen precursor in the amount of about 45 mol % depending on the desired composition of the resulting TCO coating.

g. Example Precursor Mixtures

As described above, the method of producing a high electron mobility TCO coating includes introducing one or more precursor compounds into a processing chamber. The mixture of precursor compounds may include one or more of a metal-containing precursor, a dopant precursor, a high molecular weight halogen precursor, an oxygen precursor, and a carrier gas. Table 1 below lists examples of mixtures of precursor compounds suitable for use in the method of producing a TCO coating.

TABLE 1
Example Precursor Mixtures

| | | High MW | |
|---|---|---|---|
| Metal-containing | Dopant | halogen | Oxygen |
| precursor | precursor | precursor | precursor |
| (1) | (2) | (3) | (4) |
| Sn(CH₃)₄ | SF₆ | HBr | O₂ |
| Sn(CH₃)₄ | SF₆ | HI | O₂ |
| Sn(CH₃)₄ | SF₆ | HAs | O₂ |
| Sn(CH₃)₄ | C₂F₆ | HBr | O₂ |
| Sn(CH₃)₄ | C₂F₆ | HI | O₂ |
| Sn(CH₃)₄ | C₂F₆ | HAs | O₂ |
| Sn(CH₃)₄ | SCl₆ + (1) | HBr | O₂ |
| Sn(CH₃)₄ | SCl₆ + (1) | HI | O₂ |
| Sn(CH₃)₄ | SCl₆ + (1) | HAs | O₂ |
| Sn(CH₃)₄ | C₂Cl₆ + (1) | HBr | O₂ |
| Sn(CH₃)₄ | C₂Cl₆ + (1) | HI | O₂ |
| Sn(CH₃)₄ | C₂Cl₆ + (1) | HAs | O₂ |
| SnCl₄ | SF₆ | HBr | O₂ |
| SnCl₄ | SF₆ | HI | O₂ |
| SnCl₄ | SF₆ | HAs | O₂ |
| SnCl₄ | C₂F₆ | HBr | O₂ |
| SnCl₄ | C₂F₆ | HI | O₂ |
| SnCl₄ | C₂F₆ | HAs | O₂ |
| SnCl₄ | SCl₆ + (1) | HBr | O₂ |
| SnCl₄ | SCl₆ + (1) | HI | O₂ |
| SnCl₄ | SCl₆ + (1) | HAs | O₂ |
| SnCl₄ | C₂Cl₆ + (1) | HBr | O₂ |
| SnCl₄ | C₂Cl₆ + (1) | HI | O₂ |
| SnCl₄ | C₂Cl₆ + (1) | HAs | O₂ |
| Sn(C₄H₉)₂Cl₂ | SF₆ | HBr | O₂ |
| Sn(C₄H₉)₂Cl₂ | SF₆ | HI | O₂ |
| Sn(C₄H₉)₂Cl₂ | SF₆ | HAs | O₂ |
| Sn(C₄H₉)₂Cl₂ | C₂F₆ | HBr | O₂ |
| Sn(C₄H₉)₂Cl₂ | C₂F₆ | HI | O₂ |
| Sn(C₄H₉)₂Cl₂ | C₂F₆ | HAs | O₂ |
| Sn(C₄H₉)₂Cl₂ | SCl₆ + (1) | HBr | O₂ |
| Sn(C₄H₉)₂Cl₂ | SCl₆ + (1) | HI | O₂ |
| Sn(C₄H₉)₂Cl₂ | SCl₆ + (1) | HAs | O₂ |
| Sn(C₄H₉)₂Cl₂ | C₂Cl₆ + (1) | HBr | O₂ |
| Sn(C₄H₉)₂Cl₂ | C₂Cl₆ + (1) | HI | O₂ |
| Sn(C₄H₉)₂Cl₂ | C₂Cl₆ + (1) | HAs | O₂ |
| SnC₄H₉Cl₃ | SF₆ | HBr | O₂ |
| SnC₄H₉Cl₃ | SF₆ | HI | O₂ |
| SnC₄H₉Cl₃ | SF₆ | HAs | O₂ |
| SnC₄H₉Cl₃ | C₂F₆ | HBr | O₂ |
| SnC₄H₉Cl₃ | C₂F₆ | HI | O₂ |
| SnC₄H₉Cl₃ | C₂F₆ | HAs | O₂ |
| SnC₄H₉Cl₃ | SCl₆ + (1) | HBr | O₂ |
| SnC₄H₉Cl₃ | SCl₆ + (1) | HI | O₂ |
| SnC₄H₉Cl₃ | SCl₆ + (1) | HAs | O₂ |
| SnC₄H₉Cl₃ | C₂Cl₆ + (1) | HBr | O₂ |
| SnC₄H₉Cl₃ | C₂Cl₆ + (1) | HI | O₂ |
| SnC₄H₉Cl₃ | C₂Cl₆ + (1) | HAs | O₂ |
| SnF₄ + Sn(CH₃)₄ | CBrF₃ + (1) | (2) | O₂ |
| SnF₄ + Sn(CH₃)₄ | ClF + (1) | (2) | O₂ |
| SnF₄ + Sn(CH₃)₄ | NClF₂ + (1) | (2) | O₂ |
| SnOF₂ + Sn(CH₃)₄ | ClF + (1) | (2) | O₂ + (1) |
| SnOF₂ + Sn(CH₃)₄ | NClF₂ + (1) | (2) | O₂ + (1) |
| SnF₄ + SnOF₂ | ClF + (1) | (2) | O₂ + (1) |
| SnF₄ + SnOF₂ | NClF₂ + (1) | (2) | O₂ + (1) |
| SnF₄ + SnOF₂ | ClF + (1) | (2) | O₂ + (1) |
| SnF₄ + SnOF₂ | NClF₂ + (1) | (2) | O₂ + (1) |
| SnF₄ + SnOF₂ | (1) + (3) | CBrF₃ | O₂ + (1) |

The exemplary precursor mixtures shown in Table 1 represent a small subset of the possible combinations of the various aspects of the precursor compounds described above. Note that in many of the exemplary precursor mixtures, an individual compound may provide more than one precursor function. For example, the compound SnOF₂ provide a metal, a dopant and oxygen. In another aspect, a compound such as SnOFBr would provide a metal, a dopant, a high molecular weight halogen, and oxygen in a single precursor compound. Although the use of a single precursor compound would simplify the method of producing a TCO coating, the composition and properties of the TCO material would be constrained to whatever results from the fixed proportions of metal, dopant, high molecular weight halogen, and oxygen provided by the single precursor compound.

### II. Methods of Using TCO Films

The TCO film may be used to coat a translucent substrate such as a glass plate or layer that is eventually incorporated into an electronic device component such as a photo-voltaic (PV) cell, an electroluminescent display screen, an automotive device and an aircraft device, as well as applications requiring low e-glass, among other applications. The TCO film may be used in any glass, polymers, foils, or electronic devices in which there is a desire or need for transparent conductance or wear resistant coating of a TCO containing specific ratios of heavy and low molecular weight halogens.

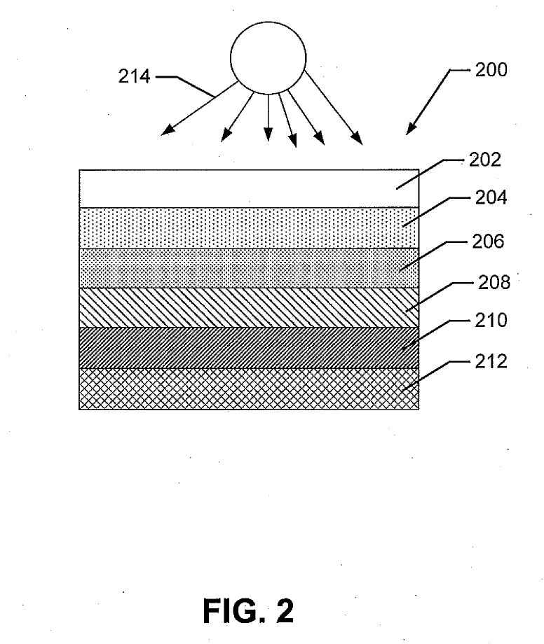

For example, a TCO coating may be used in the construction of a cadmium tellurium/cadmium sulfide (CdTe/CdS) thin photovoltaic (PV) cell, shown as a schematic illustration in FIG. 2. In the CdTe/CdS PV cell 200, an undoped SnO₂ (i-SnO2) layer 206 may be used as a buffer layer between the conductive fluorine-doped SnO₂ layer 204 and the CdS layer 208, which is layered on top of the CdTe layer 210 with attached metal contact layer 212. The i-SnO2 layer 206 may help to maintain a high open circuit voltage (V_{oc}) and fill factor (FF) for the device, thereby improving the solar cell reproducibility. Further, the enhanced optical transparency and electron mobility properties of the fluorine-doped tin oxide layer may further improve the efficiency of electrical current production by the PV cell 200, since the sunlight 214 must pass through an outer glass substrate 202, the conductive fluorine-doped SnO₂ layer 204, and the undoped SnO₂ buffer layer 206 prior to contacting the CdS window layer 208.

The enhanced degree of control over the composition, optical properties, and electrical properties of the TCO coatings made possible using the production method described above may be exploited to produce a TCO coating with a distinctive “signature” that may be used to identify an individual source of a particular TCO coating. This distinctive material signature may comprise a unique combination or unique proportion of individual chemical elements included in the composition of the TCO coating, where the individual elements may include, but are not limited to, individual metal elements, dopant elements, heavy molecular weight halogens, or a non-functional metal, radioactive isotope, or other element included in the TCO coating at trace levels to provide a means of identifying the individual producer of the TCO coating. While a number of exemplary aspects and embodiments have been discussed above, those of skill in the art will recognize certain modifications, permutations, additions and sub combinations thereof. It is therefore intended that the following appended claims and claims hereafter introduced are interpreted to include all such modifications, permutations, additions and sub-combinations as are within their true spirit and scope.

What is claimed is:

1. A method of producing a transparent conducting oxide (TCO) coating on a substrate, the method comprising:
heating the substrate in a processing chamber;
introducing a metal-containing precursor and one or more dopant precursors comprising a high molecular weight halogen and a low molecular weight halogen into the processing chamber, forming a reactive mixture, wherein the ratio of the high molecular weight halogen to low molecular weight halogen is a predetermined ratio; and
transporting the reactive mixture into close proximity with the heated substrate to form a deposited layer comprising the transparent conducting oxide attached to the substrate, wherein the TCO has a Hall mobility ranging between about 20 cm²V⁻¹ s⁻¹ and about 200 cm²V⁻¹ s⁻¹ and a carrier concentration ranging between about 10¹⁷ cm⁻³ and about 10²² cm⁻³.

2. The method of claim 1, wherein the TCO coating has a composition chosen from doped tin oxide (SnO₂), doped cadmium oxide (CdO), doped cadmium tin oxide (Cd₂SnO₄), doped zinc oxide, doped indium oxide/tin oxide (In₂O₃:SnO₂), tin oxide, zinc oxide, cadmium oxide, silicon oxide, indium-tin oxide, and combinations thereof.

3. The method of claim 1, wherein the processing chamber is a CVD chamber chosen from a low pressure CVD chamber, an atmospheric-pressure CVD chamber, an ultra-high vacuum CVD chamber, and a plasma-assisted CVD chamber.

4. The method of claim 1, wherein the processing charge is comprised for spray pyrolysis.

5. The method of claim 1, wherein the substrate comprises a material chosen from glass, silica, cadmium sulfide (CdS), undoped TCO coatings such as tin oxide (SnO₂), cadmium oxide (CdO), cadmium tin oxide (Cd₂SnO₄), zinc oxide (ZnO), and indium oxide/tin oxide (In₂O₃:SnO₂).

6. The method of claim 1, wherein the metal-containing precursor is chosen from tetramethyltin (TMT), tin tetrachloride, dibutyl tin chloride, monobutyl tin chloride, tetraethyltin, monobutyltin oxide, dibutyltin oxide, mono/dibutyltin chlorides, dimethyltin dichloride, tin tetrafluoride, tin trichlorofluoride (SnCl₃F), SnCl₂F₂, SnIF₃, SnBrF₃, Sn(CF₃)₄, SnOF₂, SnO(CF₃)₂, SnOClF, SnOIF, SnOBrF, and combinations thereof.

7. The method of claim 1, wherein the one or more dopant precursors are chosen from Halocarbons 116, 1216, 14, 218, 23, 32, 41, 4110, and/or C318, C₂BrF₃, CH₃F, CF₄, CF₂O, CHClF₂, C₂ClF₅, C₂ClF₃, CClF₃, CBr₂F₂, C₂Br₂F₄, CCl₂F₂, CHCl₂F, C₂Cl₂F₄, C₂H₃ClF₂, C₂H₄F₂, C₂H₂F₂, CH₂F₂, C₃F₆O, C₂F₆, C₃F₆, C₄F₈, C₄F₈O, C₅F₈, C₂H₅F, C₄F₁₀, C3F₈, C₂F₄, CCl₃F, C₂Cl₃F₃, CHF₃, C₂H₃F, and C₃F₇OCH₃, BF₃, HF, F₂O, SiF₄, SF₆, SF₄, S₂F₁₀, WF₆, AsF₅, PF₃, BrF₅, BrF₃, IF₅, ClF₃, NF₃, N₂F₄, ClF, BrF, ClF₂N, FCl₂N, XeF₂, GeF₄, ClF₃, F₂, a mixture of F₂ and O₂, a mixture of HF and O₂, F₃NO, FNO, COF₂, CF₃NO, CF₃OF, CF₃I, SClF₅, SO₂F₂, NCl₂F, NF₂Cl, ClFO₃, C₄F₉OCH₃, C₄F₉OC₂H₅, CF₃OCH₃, CHF₂OCHF₂, CF₃CF₂OCH₃, CF₃OCHFCF₃, CF₃COCBr₂H, and combinations thereof.

8. The method of claim 1, wherein the processing chamber and substrate are heated to a temperature ranging from about 400° C. to about 700° C.

9. The method of claim 1, further comprising introducing a high molecular weight halogen precursor into the processing chamber with the metal-containing precursor and the one or more dopant precursors.

10. The method of claim 9, wherein the high molecular weight halogen precursor is chosen from BrF₃C, IF₃C, HBr, HI, HAs, and combinations thereof.

11. The method of claim 9, further comprising introducing an oxygen, oxide, or oxygen-containing precursor into the processing chamber with the metal-containing precursor and the one or more dopant precursors.

12. The method of claim 11, wherein the oxygen, oxide or oxygen-containing precursor is chosen from atomic oxygen (O), molecular oxygen (O₂), O₃, N₂O, NO, NO₂, OH, H₂O, H₂O₂, SO, SO₂, CO₂, C₃H₇OH, C₂H₅OH, and combinations thereof.

13. The method according to claim 1, wherein the predetermined ratio is optimized for one or more of electron mobility, transparency, crystal structure, surface roughness, carrier concentration and haze.

14. A method of producing a transparent conducting oxide (TCO) coating on a substrate, the method comprising:
heating the substrate in a processing chamber;
introducing a metal-containing precursor, one or more dopant precursors, and a high molecular weight halogen precursor into the processing chamber, forming a reactive mixture, wherein precursor molecules are configured to contain predetermined optimized ratios of high and low molecular weight halogens; and
contacting the reactive mixture with the heated substrate to form a deposited layer comprising the transparent conducting oxide attached to the substrate, wherein the TCO has a Hall mobility ranging between about 20 cm²V⁻¹ s⁻¹ and about 200 cm²V⁻¹ s⁻¹ and a carrier concentration ranging between about 10¹⁷ cm⁻³ and about 10²² cm⁻³.

15. The method of claim 14, wherein the TCO coating has a composition chosen from doped tin oxide (SnO₂), doped cadmium oxide (CdO), doped cadmium tin oxide (Cd₂SnO₄), doped zinc oxide, doped indium oxide/tin oxide (In₂O₃:SnO₂), tin oxide, zinc oxide, cadmium oxide, silicon oxide, indium-tin oxide, Pb—Zr—Ti oxide, mercury-barium oxide, mercury-barium-copper oxide, doped mercury-barium oxide, doped mercury-barium-copper oxide, and combinations thereof.

16. The method of claim 14, wherein the processing chamber is a CVD chamber chosen from a low pressure CVD chamber, an atmospheric-pressure CVD chamber, an ultra-high vacuum CVD chamber, and a plasma-assisted CVD chamber.

17. The method of claim 14, wherein the substrate comprises a material chosen from glass, silica, cadmium sulfide (CdS), undoped TCO coatings such as tin oxide (SnO₂), cadmium oxide (CdO), cadmium tin oxide (Cd₂SnO₄), zinc oxide (ZnO), and indium oxide/tin oxide (In₂O₃:SnO₂).

18. The method of claim 14, wherein the metal-containing precursor is chosen from tetramethyltin (TMT), tin tetrachloride, dibutyl tin chloride, monobutyl tin chloride, tetraethyltin, monobutyltin oxide, dibutyltin oxide, mono/dibutyltin chlorides, dimethyltin dichloride, tin tetrafluoride, tin trichlorofluoride (SnCl₃F), SnCl₂F₂, SnIF₃, SnBrF₃, Sn(CF₃)₄, SnOF₂, SnO(CF₃)₂, SnOClF, SnOIF, SnOBrF, and combinations thereof.

19. The method of claim 14, wherein the one or more dopant precursors are chosen from Halocarbons 116, 1216, 14, 218, 23, 32, 41, 4110, and/or C318, C₂BrF₃, CH₃F, CF₄, CF₂O, CHClF₂, C₂ClF₅, C₂ClF₃, CClF₃, CBr₂F₂, C₂Br₂F₄, CCl₂F₂, CHCl₂F, C₂Cl₂F₄, C₂H₃ClF₂, C₂H₄F₂, C₂H₂F₂, CH₂F₂, C₃F₆O, C₂F₆, C₃F₆, C₄F₈, C₄F₈O, C₅F₈, C₂H₅F, C₄F₁₀, C3F₈, C₂F₄, CCl₃F, C₂Cl₃F₃, CHF₃, C₂H₃F, and C₃F₇OCH₃, BF₃, HF, F₂O, SiF₄, SF₆, SF₄, S₂F₁₀, WF₆, AsF₅, PF₃, BrF₅, BrF₃, IF₅, ClF₃, NF₃, N₂F₄, ClF, BrF, ClF₂N, FCl₂N, XeF₂, GeF₄, ClF₃, F₂, a mixture of F₂ and O₂, a mixture of HF and O₂, F₃NO, FNO, COF₂, CF₃NO, CF₃OF, CF₃I, SClF₅, SO₂F₂, NCl₂F, NF₂Cl, ClFO₃, C₄F₉OCH₃, C₄F₉OC₂H₅, CF₃OCH₃, CHF₂OCHF₂, CF₃CF₂OCH₃, CF₃OCHFCF₃, CF₃COCBr₂H, and combinations thereof.

20. The method of claim 14, wherein the high molecular weight halogen precursor is chosen from BrF₃C, IF₃C, HBr, HI, HAs, and combinations thereof.

21. The method of claim 14, wherein the processing chamber and substrate are heated to a temperature ranging from about 400° C. to about 700° C.

22. The method of claim 14, further comprising introducing an oxygen precursor into the processing chamber with the metal-containing precursor, the one or more dopant precursors and the high molecular weight halogen precursor.

23. The method of claim 22, wherein the oxygen precursor compound is chosen from atomic oxygen (O), molecular oxygen (O₂), O₃, N₂O, NO, NO₂, OH, H₂O, H₂O₂, SO, SO₂, CO₂, C₃H₇OH, C₂H₅OH, and combinations thereof.

24. The method according to claim 14, wherein the predetermined ratio is optimized for one or more of electron mobility, transparency, crystal structure, surface roughness, carrier concentration and haze.

25. An apparatus comprising at least one transparent conducting oxide (TCO) coating on a substrate produced using the method described in claim 14, wherein the apparatus is chosen from a photo-voltaic (PV) cell, an electroluminescent display screen, an automotive device, an aircraft device, and a low e-glass.

26. The apparatus of claim 25, wherein the apparatus is a photovoltaic cell comprising:
an undoped SnO₂ coating formed on a glass substrate;
a fluorine-doped SnO₂ coating formed on the surface of the undoped SnO₂ coating opposite to the glass substrate; and,
a CdS window layer attached to the surface of the fluorine-doped SnO₂ coating opposite to the undoped SnO₂ coating.

27. A coating for glass, polymers, foils or electronic devices, the coating comprising:
a transparent conducting oxide (TCO); wherein the TCO has a composition chosen from doped tin oxide (SnO₂), doped cadmium oxide (CdO), doped cadmium tin oxide (Cd₂SnO₄), doped zinc oxide, doped indium oxide/tin oxide (In₂O₃:SnO₂), tin oxide, zinc oxide, cadmium oxide, silicon oxide, indium-tin oxide, Pb—Zr—Ti oxide, mercury-barium oxide, mercury-barium-copper oxide, doped mercury-barium oxide, doped mercury-barium-copper oxide, and combinations thereof, wherein the TCO is optimized for one or more of electron mobility, transparency, crystal structure, surface roughness, carrier concentration and haze.
